(19) United States
(12) Patent Application Publication
(10) Pub. No.: US 2005/0106896 A1
(43) Pub. Date: May 19, 2005

(54) Processing apparatus and method

(75) Inventor: Yusuke Fukuchi, Ibaraki (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/766,854

(22) Filed: Jan. 30, 2004

(30) Foreign Application Priority Data
Nov. 19, 2003 (JP) 2003-389876

(51) Int. Cl. H01L 21/31; H01L 21/469

(52) U.S. Cl. 438/778; 438/791

(57) ABSTRACT

A processing method for forming an insulated film on a surface of a substrate to be processed, through an oxynitriding treatment includes the steps of nitriding a surface of the substrate by irradiating plasma containing nitrogen atoms onto the substrate, and oxidizing the surface of the substrate, which has been nitrided, by irradiating plasma containing oxygen atoms.

This application claims a benefit of priority based on Japanese Patent Application No. 2003-389876, filed on Nov. 19, 2003, which is hereby incorporated by reference herein in its entirety as if fully set forth herein.

### BACKGROUND OF THE INVENTION

The present invention relates generally to a processing apparatus and method, and more particularly to a plasma processing method and apparatus. The present invention is suitable, for example, plasma processing for control over a thickness of an insulated film for a semiconductor device.

A silicon dioxide film that has conventionally been used for an insulated film for a metal oxide semiconductor (“MOS”) type semiconductor device is provided with high band gap energy and excellent interface characteristics, and has supported highly reliable semiconductor performance. The current high integration, such as very large scale integration, has thinned the gate insulated film for the MOS transistor down to 2 nm or smaller.

The conventional silicon dioxide film has a difficulty in maintaining its performance as an insulated film in a thin film region, due to abruptly lowered dielectric voltage and remarkable increase of leak current caused by direct tunnel current. The conventional silicon dioxide film has been formed by oxidizing a silicon substrate while heating it above 1000° C. under an oxygen gas or steam atmosphere. This high-temperature treatment applies high heat load to the substrate, causing rediffusions of impurities that have already existed in the substrate, and preventing fine processing.

Accordingly, use of a material with high dielectric constant (High-k) as an insulated film has been developed which can not only maintain performance and a physical thickness similar to those of the MOS semiconductor device that uses the conventional silicon dioxide film as an insulated film, but also realizes a lower effective film thickness. In particular, a silicon nitride film and a silicon oxynitride film exhibit excellent characteristics, such as higher affinity to the conventional semiconductor manufacture process, and a function to restrain diffusions of boron implanted to a P+Poly gate electrode in the substrate, and thus have been considered to be prospective materials for gate insulated films with 90 nm node or smaller.

Various manufacture methods have been proposed for the silicon nitride film and the silicon oxynitride film, such as a method of depositing a silicon nitride film on a silicon substrate with ammonia (NH₃) and monosilane (SiH₄), such as thermal CVD and plasma CVD, a nitriding method using an abruptly heated nitrogen-containing atmosphere, such as nitrogen and NH₃, at a temperature between 800 and 1200° C., and a method of forming a silicon oxide film on a silicon substrate through thermal oxidation and of heating the silicon oxide film under a nitrogen-containing atmosphere, such as N₂ and NH₃. Japanese Patent Application Publication No. 2002-198522, for example, has proposed thermal nitriding.

However, various disadvantages have been pointed out in the nitride film formed by a conventional method, such as more fixed charges and interface levels than a SiO₂ film, causing low flat band voltage and electron mobility. A nitride introduction under the heated high-temperature atmosphere would cause rediffusions of impurities that have already existed in a silicon substrate, making a shallow junction formation difficult, and preventing fine processing.

### BRIEF SUMMARY OF THE INVENTION

Accordingly, it is an exemplary object of the present invention to provide a processing apparatus and method that forms a reliable insulated film without using a heated high-temperature atmosphere.

A processing method of one aspect according to the present invention for forming an insulated film on a surface of a substrate to be processed, through an oxynitriding treatment includes the steps of nitriding a surface of the substrate by irradiating plasma containing nitrogen atoms onto the substrate, and oxidizing the surface of the substrate, which has been nitrided, by irradiating plasma containing oxygen atoms.

The nitriding and oxidizing steps may place the substrate on a susceptor, a temperature of the susceptor being maintained at 600° C. or lower. The substrate include silicon, and the nitriding and oxidizing steps control a process time so that the insulated film has an effective oxide thickness (“EOT”) of 3.0 nm or smaller. The nitriding step uses, as process gas, for example, gas that includes at least one of N₂, NH₃ and N₂H₄ or the one which is diluted with at least one of He, Ne, Ar, Kr and Xe, mixed gas of H₂+N₂ or the one which is diluted with at least one of He, Ne, Ar, Kr and Xe. The oxidizing step gas uses, as process gas, for example, gas that includes at least one of O₂, O₃, H₂O, and H₂O₂ or the one which is diluted with at least one of He, Ne, Ar, Kr, Xe and N₂.

The oxidizing step preferably sets ion energy to be 5 eV or smaller incident to the substrate from the plasma. The substrate preferably includes silicon, and the oxidizing step preferably controls an oxygen atom concentration so that a nitrogen atom concentration is 5% or smaller at a position near an interface between the silicon and a silicon oxynitride film in the insulated film. The nitriding step preferably controls a process time so that the insulated film contains the nitrogen atoms between 3×10¹⁴ cm⁻² and 1.5×10¹⁵ cm⁻² that is converted into a surface density.

Other objects and further features of the present invention will become readily apparent from the following description of the preferred embodiments with reference to accompanying drawings.

### BRIEF DESCRIPTION OF THE DRAWINGS

FIG. 1 is a schematic sectional view of a microwave plasma processing apparatus of one embodiment according to the present invention.

FIG. 2 is a schematic sectional view for explaining a process flow of an insulated film with the microwave plasma processing apparatus shown in FIG. 1.

FIG. 3 is a schematic sectional view of a microwave plasma processing apparatus of a first embodiment according to the present invention.

FIG. 4 is a graph for explaining a nitrogen concentration profile in an insulated film generated with the plasma processing apparatus shown in FIG. 3.

FIG. 5 is a schematic sectional view of a microwave plasma processing apparatus of a second embodiment according to the present invention.

FIG. 6 is a schematic sectional view of a microwave plasma processing apparatus of a third embodiment according to the present invention.

FIG. 7 is a graph showing temperature dependency of a diffusion coefficient of impurities in silicon crystal.

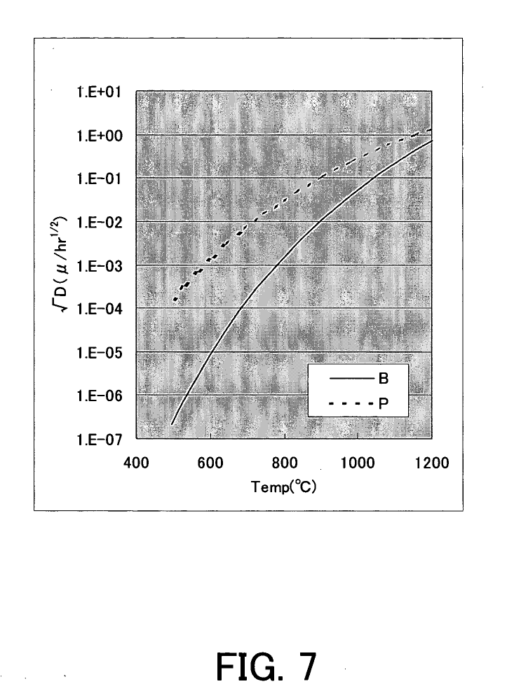

FIG. 8 is a schematic block diagram of a process system that applies the microwave plasma processing apparatus shown in FIG. 1.

FIG. 9 is a flowchart for explaining plasma processing of the instant embodiment.

### DETAILED DESCRIPTION OF THE PREFERRED EMBODIMENTS

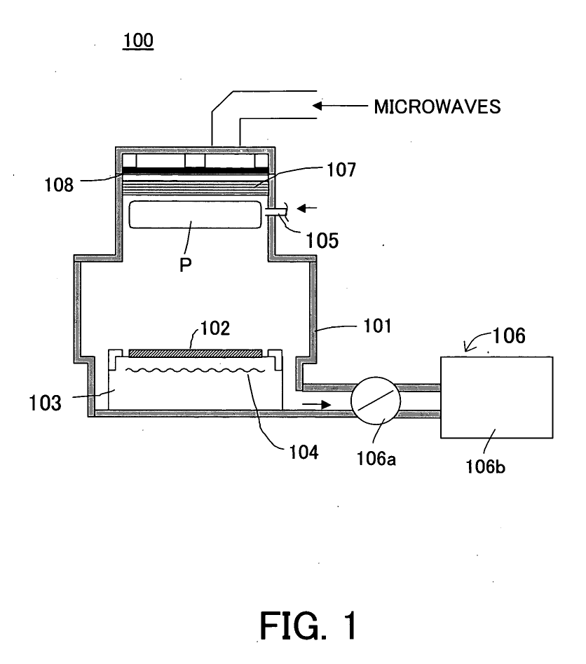

A detailed description will now be given of a microwave plasma processing apparatus (simply referred to as a “processing apparatus” hereinafter) 100 of one embodiment according to the present invention with reference to accompanying drawings. Here, FIG. 1 is a schematic sectional view of the processing apparatus 100. As illustrated, the processing apparatus 100 is connected to a microwave or high-frequency oscillator (generator or source) (not shown), includes a plasma process chamber (or vacuum container) 101 substrate to be processed 102, a susceptor (or a support table) 103, a temperature control part 104, a gas introducing part 105, a pressure control mechanism 106, a dielectric window or high-frequency transmission window 107, and a microwave supply unit or high-frequency power supply unit 108, and applies a plasma treatment to the substrate 102.

The microwave oscillator is, for example, a magnetron and generates microwaves, for example, of 2.45 GHz. Nevertheless, the present invention can select any appropriate microwave frequency between 0.8 GHz and 20 GHz. The microwaves are then converted by a mode converter into a TM or TE mode or the like, before propagating through a waveguide. The microwave waveguide channel is equipped with an isolator, an impedance matching unit, and the like. The isolator prevents reflected microwaves from returning to the microwave oscillator, and absorbs the reflected waves. The impedance matching unit, which is made of a 4E tuner, an EH tuner, a stab tuner, etc., includes a power meter that detects the strength and phase of each of a progressive wave supplied from the microwave oscillator to the load and a reflected wave that is reflected by the load and returning to the microwave oscillator, and serves to match between microwave oscillator and a load side.

The plasma excitation means can apply a plasma source of any one of an inductive coupling type, a capacitive coupling type, a surface wave type, a magnetron type, an electron cyclotron resonance type, etc. The nitriding and oxidation processes can use the same plasma source or different plasma sources.

The plasma process chamber 101 is a vacuum container that accommodates the substrate 102 and provides a plasma treatment to the substrate 102 under a reduced pressure or vacuum environment. FIG. 1 omits a gate valve that receives the substrate 102 from and feeds the substrate 102 to a load lock chamber (not shown), and the like.

The substrate 102 is placed on the susceptor 103. If necessary, the susceptor 103 is made height-adjustable. The susceptor 103 is accommodated in the plasma process chamber 101, and supports the substrate 102.

The temperature control part 104 includes a heater, etc., which controls the temperature suitable for treatments, for example, equal to or lower than 600° C., e.g., between 200° C. and 400° C. The temperature control part 104 includes, for example, a thermometer that detects the temperature of the susceptor 103, and a controller that controls electrification from a power source (not shown) to a heater line.

The temperature should be equal to or lower than 600° C. because the high temperature promotes diffusions of impurities that have already existed in the substrate, and prevents fine processing.

The gas introducing part 105 is provided at the top of the plasma process chamber 101, and supplies gas for a plasma treatment into the plasma process chamber 101. The gas introducing part 105 is part of gas supply means that includes a gas source, a valve, a mass flow controller, and a gas pipe that connects them, and supplies process gas and discharge gas to be excited by the microwaves for predetermined plasma. It may add inert gas, such as Xe, Ar and He for prompt plasma ignitions at least at the ignition time. The inert gas ionizes easily, and improves plasma ignitions at the time of microwave introduction. As described later, the gas introducing part 105 is partitioned, for example, into an inlet that introduces process gas, and another inlet that introduces inert gas, and positions these inlets at different positions.

The instant embodiment provides an oxynitriding treatment with nitriding and oxidizing gases. The oxidizing gas to oxide the surface of the substrate 102 includes O₂, O₃, H₂O, H₂O₂, NO, N₂O, NO₂, etc., and the nitriding gas to nitride the surface of the substrate 102 includes N₂, NH₃, N₂H₄, hexamethyldisilazane (HMDS), blended gas of H₂+N₂ etc. As discussed, the process gas may be mixed air that has been diluted by at least one type of gas He, Ne, Ar, Kr, Xe and N₂.

The pressure control mechanism 106 is provided at a lower portion or bottom of the plasma process chamber 101, and includes a pressure regulating valve 106a, a pressure sensor (not shown), a vacuum pump 106b, and a controller (not shown). The controller (not shown) drives the vacuum pump 106b and controls the pressure in the plasma process chamber 101 by controlling the pressure regulating valve 106a, such as a VAT Vakuumventile A.G. (“VAT”) manufactured gate valve that has a pressure regulating function and an MKS Instruments, Inc. (“MKS”) manufactured exhaust slot valve, so that the pressure sensor for detecting the pressure in the process chamber 101 detects a predetermined value. As a result, the pressure control mechanism 106 controls the internal pressure of the plasma process chamber 101 suitable for processing. The pressure is preferably set in a range between 13 mPa and 1330 Pa, more preferably between 665 mPa and 665 Pa. The vacuum pump 106b includes, for example, a turbo molecular pump (TMP), and is connected to the plasma process chamber 101 via the pressure control valve (not shown), such as a conductance valve.

The dielectric window 107 transmits the microwaves supplied from the microwave oscillator to the plasma process chamber 101, and serves as a diaphragm for the plasma process chamber 101.

The slot-cum plane microwave supply unit 108 serves to introduce the microwaves into the plasma process chamber 101 via the dielectric window 107, and can use a slot-cum non-terminal circle waveguide and a coaxial introducing plane multi-slot antenna when it can supply plane microwaves. The plane microwave supply unit 108 used for the inventive microwave plasma processing apparatus 100 can use a conductor, preferably those which have high conductivity for reduced microwave transmission losses, such as Al, Cu and SUS plated with Ag/Cu.

When the slot-cum plane microwave supply unit 108 is, for example, a slot-cum non-terminal circle waveguide, it includes a cooling channel and a slot antenna. The slot antenna forms a surface standing wave through interference of surface waves on the surface of the dielectric window 107 at its vacuum side. The slot antenna is a metal disc having, for example, radial slots, circumferential slots, multiple concentric or spiral T-shaped slots, and four pairs of V-shaped slots. An uniform treatment over the entire surface of the substrate 102 needs a supply of active species with good in-plane uniformity. The slot antenna arranges at least one slot, generates the plasma over a large area, and facilitates control over the plasma strength and uniformity.

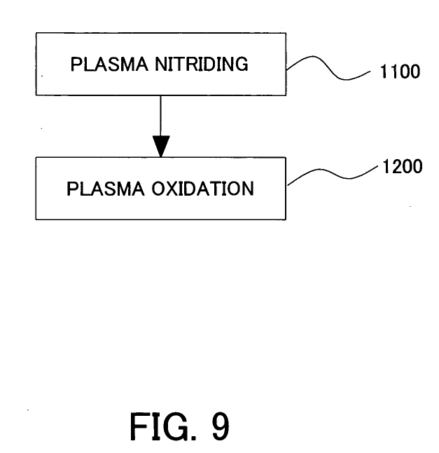

Referring now to FIG. 9, a description will be given of a formation of an oxynitride (or insulated) film using the processing apparatus 100. First, the substrate 102 is placed on the susceptor 103 after the surface of substrate 102 is cleansed by a known RCA and a diluted hydrofluoric acid cleaning method. Then, the pressure control mechanism 106 exhausts the plasma process chamber 101. Then, the gas introducing part 105 opens a valve (not shown) and introduces the process gas at a predetermined flow rate into the plasma process chamber 101 through the mass flow controller. Then, a pressure control valve 106a is adjusted to maintain the plasma process chamber 101 at a predetermined pressure. The microwave oscillator supplies the microwaves to the plasma process chamber 101 via the microwave supply unit 108 and the dielectric window 107, and generates the plasma in the plasma process chamber 101. Microwaves introduced into the microwave supply unit 108 propagate with an in-tube wavelength longer than that in the free space, are introduced into the plasma process chamber 101 via the dielectric window 107 through the slots, and transmit as a surface wave on the surface of the dielectric window 107. This surface wave interferes between adjacent slots, and forms a surface standing wave. The electric field of this surface standing wave generates high-density plasma. The plasma generating region has the high electron density and allows the process gas to effectively get isolated. The electric field localizes near the dielectric window and the electron temperature rapidly lowers as a distance from the plasma generation part increases, lowering damages to the device. The active species in the plasma are transported to and near the substrate 102 through diffusion, etc., and reach the surface of the substrate 102.

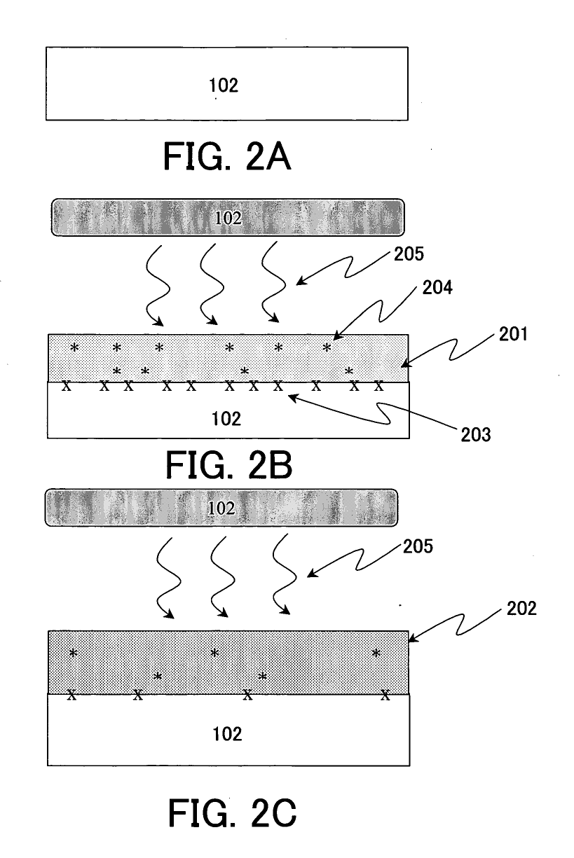

The instant embodiment provides a nitriding treatment (step 1100) and then an oxidization treatment (step 1200) after exchanging a gas source; it conducts both the nitriding and oxidization treatments in the same process chamber 101. A description will be given of them with reference to FIG. 2. Here, FIG. 2A is a schematic sectional view of the cleansed substrate 102. FIG. 2B is a schematic sectional view of the nitrided substrate 102. FIG. 2C is a schematic sectional view of the oxidized substrate 102.

A silicon nitride film 201 is formed on the substrate 102, as shown in FIG. 2B, as a result of that the substrate 102 is exposed to generated nitrogen plasma 205. After the silicon nitride film is formed with a desired thickness, supplies of discharge and process gases are stopped, and the exhaust means sufficiently exhausts the vacuum container again. After exhaustion, the gas introducing part 105 introduces oxygen process gas to maintain the process chamber 101 at a predetermined pressure. Then, the microwave supply unit 108 introduces the microwaves through the dielectric window 107 and forms the plasma P. The silicon nitride film is modified into a silicon oxynitride (or insulated) film on the substrate 102, as shown in FIG. 2C, when the substrate 102 is exposed to the oxygen plasma. 204 is a space fixed charge. The insulated film has a thickness of 3.0 nm or smaller which is converted into an effective oxide thickness (EOT).

Similar to the nitride film formed by the conventional method, the silicon nitride film 201 formed on the substrate 102 in the instant embodiment has a region of incomplete bonds between silicon and nitrogen due to distorted silicon's crystal lattice near an interface between the silicon substrate 102 and the silicon nitride film 201, and there is a defect that acts as an interface level 203. In addition, the insulated film has a non-terminated bond between a silicon atom and a nitrogen atom, which is a dangling bond or space fixed charge. In the plasma oxidation treatment subsequent to the plasma nitriding treatment, reactive oxygen plasma restructures an atomic arrangement near the interface, flattens the silicon substrate interface in an atomic level, and mitigates bonding distortions between the silicon atoms and nitrogen atoms. Terminations of dangling bonds in the film would provide a high-quality insulated film having a small interface level and a small amount of fixed charges.

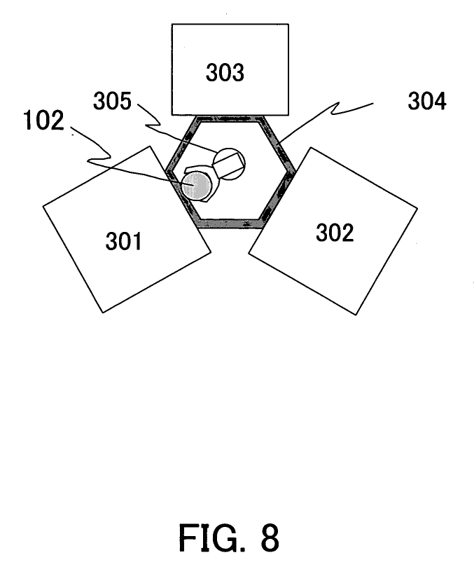

While the silicon nitride film forming treatment and the oxidation treatment share the same process chamber in the instant embodiment, but they can use different process chambers. That case preferably uses a cluster type apparatus with a wafer load lock chamber and performs a series of processing from the nitride film forming treatment to the oxidation treatment under a highly vacuum atmosphere. FIG. 8 shows this embodiment, and a schematic block diagram of a processing system. The processing system includes plasma process chambers 301 and 302, a substrate load chamber 303, a feed chamber 304, and a feed means 305. The plasma process chambers 301 and 302 each include the processing apparatus 100 shown in FIG. 1, and the substrate load chamber 303 stores the oxynitrided substrate 102. The feed chamber 304 has a feed means (or robot) to feed the substrate 102, and a controller for controlling the feed means. The feed means 305 has a 360° rotatable base, and a mechanism for holding and feeding the substrate 102, and for delivering the substrate 102 among the plasma process chambers 301 and 302 and substrate load chamber 303. The feed chamber 304 and the feed means 305 can apply any technology known in the art, such as a cluster tool, and a detailed description thereof will be omitted.

In operation, the feed means 305 receives the cleansed substrate 102 from the substrate load chamber 303 and introduces it into the plasma process chamber 301. The plasma process chamber 301 provides a plasma nitriding treatment to the substrate 102. After the plasma nitriding treatment, the feed means 305 receives the substrate 102 from the plasma process chamber 301 and introduces it to the plasma process chamber 302. The plasma process chamber 302 provides a plasma oxidization treatment to the substrate 102. After the plasma oxidization treatment, the feed means 305 receives the substrate 102 from the plasma process chamber 302 and stores it in the substrate load chamber 303.

This insulated film in the instant embodiment is a high-quality insulated film that has high dielectric constant, and low fixed charges and interface low density. Moreover, nitrogen atoms introduced in the insulated film can prevent diffusions of impurities, such as boron, towards the substrate. It can be used as a single insulated film, or a primary coat for another high dielectric-constant material.

After forming a silicon nitride film using the nitrogen plasma, the instant embodiment introduces active oxygen atoms into a vicinity of the interface between the silicon substrate and the silicon nitride film and into the film. A resultant rearrangement of silicon and nitrogen atoms in the film mitigates distortions in the interface, and lowers various defects, such as disadvantageous interface levels and fixed charges in the silicon nitride film, caused by bonding with dangling bonds. In addition to the nitriding and oxidation processes, the plasma process at a low temperature of 600° C. or lower can form an insulated film that maintains the low thermal load relative to the substrate without rediffusing impurities in the substrate, and preventing shallow bonding necessary for fine processing. The quality of the formed insulated film is controllable by changing a process condition of a nitride film initially formed on the silicon substrate and a process condition of an oxide film formed on the silicon nitride film.

The silicon nitride film's thickness and the nitrogen-atom content introduced in the film are controllable by changing a process condition of a nitride film initially formed on the silicon substrate and a process condition of an oxide film formed on the silicon nitride film. The nitrogen-atom concentration distribution in the depth direction in the film is controllable by changing the oxidation treatment time and temperature, and the incident oxygen-ion energy.

The preferable incident oxygen-ion energy introduced into the substrate is 5 eV or lower to avoid damages caused by high-energy oxygen-ion implantation to the insulated film. The oxygen-ion energy control method includes a method of changing the sheath potential by plasma excitation means, pulsed application timing of the high-frequency electric field, process conditions, etc., a method that uses a power source that applies the bias voltage to the substrate, etc.

In order to obtain a high dielectric constant with small interface defects, nitrogen atoms in the insulated film preferably form an oxygen-atom concentration profile so that the nitrogen atom concentration becomes 5% or smaller at a position near the interface between silicon and silicon oxynitride film. In addition, in order to prevent diffusions of impurities, such as boron, and to obtain sufficiently high dielectric constant, the nitrogen-atom content in the insulated film is preferably between 3×10¹⁴ cm⁻² and 1.5×10¹⁵ cm⁻² when converted into a surface density.

The thus-formed silicon oxynitride film is singularly suitable for a primary barrier coat for a higher dielectric-constant High-k film, such as HfO₂ and ZrO₂, in addition to a gate insulated film for metal insulator semiconductor field effect transistor (“MISFET”) and, a capacitor insulated film in a MIS structure memory device. The High-k material is applicable to metal oxides that have a primary ingredient of Al, Hf, Zr, Ti, Ta, etc., or a silicate film thereof, or rear earth oxides that have a primary ingredient of Y, La, Ce, Pr, Nd, Gd, Dy, Ho, Yb, etc.

The processing apparatus 100 may use magnetic generating means for processing at lower pressure. Any magnetic field is applicable to the inventive plasma processing apparatus and method if it is perpendicular magnetic field to an electric field generated in a slot width direction. The magnetic field generation means can employ a permanent magnet in addition to a coil. When the coil is used, other cooling means can be used, such as water cooling and air cooling.

A description will be given of specific embodiment of the microwave plasma processing apparatus 100, but the present invention is not limited to these embodiments:

### First Embodiment

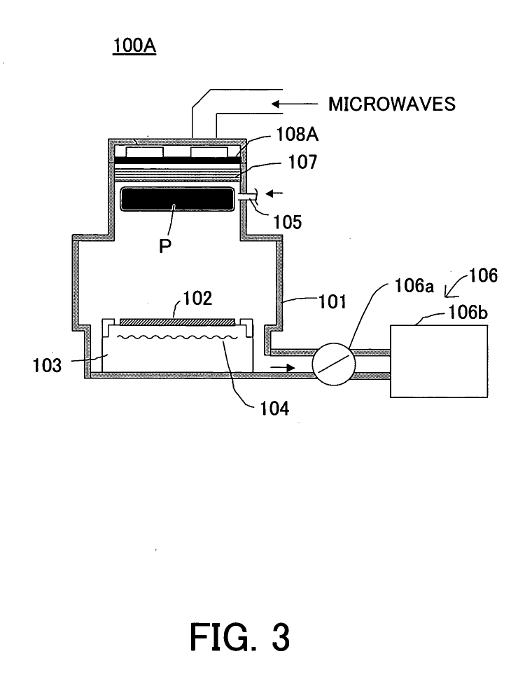

This embodiment used a microwave plasma processing apparatus 100A shown in FIG. 2 as one example of the processing apparatus 100 to form a gate oxide film for a semiconductor device. The processing apparatus 100A uses the microwaves to excite surface-wave interference plasma, and continuously performs the nitriding and oxidization treatments in the same process chamber. 108A is a slot-cum non-terminal circle waveguide for introducing the microwaves into the plasma processing chamber 101 through the dielectric window 107. Those elements in FIG. 3 which are the same as those in FIG. 1 are designated by the same reference numeral, and which are variations or specific examples of those in FIG. 1 are designated by the same reference numeral with a capital.

The slot-cum non-terminal circle waveguide 108A has a TE₁₀ mode, a size of an internal wall section of 27 mm×96 mm (with a guide wavelength of 158.8 mm) and a central diameter of the waveguide of 151.6 mm (one peripheral length is three times as long as the guide wavelength). The slot-cum non-terminal circle waveguide 108A is made of aluminum alloy for a reduced propagation loss. The slot-cum non-terminal circle waveguide 108A forms slots on its H surface, which introduce the microwaves into the plasma process chamber 101. There are six radial rectangular slots at a central diameter of 151.6 mm and 60° intervals with a length of 40 mm and a width of 4 mm. The slot-cum non-terminal circle waveguide 108A is connected to a 4E tuner, a directional coupler, an isolator, and a microwave power source (not shown) having a frequency of 2.45 GHz in this order.

The substrate 102 used an 8-inch P-type single crystal silicon substrate with a surface azimuth of <1 0 0> and resistivity of 10 Ωcm. First, the substrate 102 was fed to the plasma process chamber 101 and placed on the susceptor 103. The heater 104 heated the substrate 102 up to 300° C. and maintained the temperature.

Then, N₂ gas was introduced into the process chamber 101 at a flow rate of 200 sccm, to adjust an opening of the pressure control valve 106a in the pressure control mechanism 106, and to hold the pressure in the process chamber 101 to be 133 Pa. Then, the microwave supply unit 108A supplied 1 kW microwave power at 2.45 GHz to the process chamber 101 through the dielectric window 107, and generated plasma P in the process chamber 101. The substrate 102 was exposed to the generated nitrogen plasma for 60 seconds to form a silicon nitride film. As a result of that an ellipsometer measured a thickness of the silicon nitride film, the thickness was found to be 1.8 nm.

After the vacuum pump sufficiently draws a vacuum in the process chamber 101 down to 10⁻³ Pa, O₂ gas was introduced at a flow rate of 200 sccm, to adjust an opening of the pressure control valve 106a and to hold the pressure in the process chamber 101 to be 400 Pa. Then, the microwave supply unit 108A supplied 1 kW microwave power at 2.45 GHz to the process chamber 101 through the dielectric window 107, and generated plasma P in the process chamber 101. The substrate 102 was exposed to the generated oxygen plasma for 30 seconds to modify it into a silicon oxynitride film.

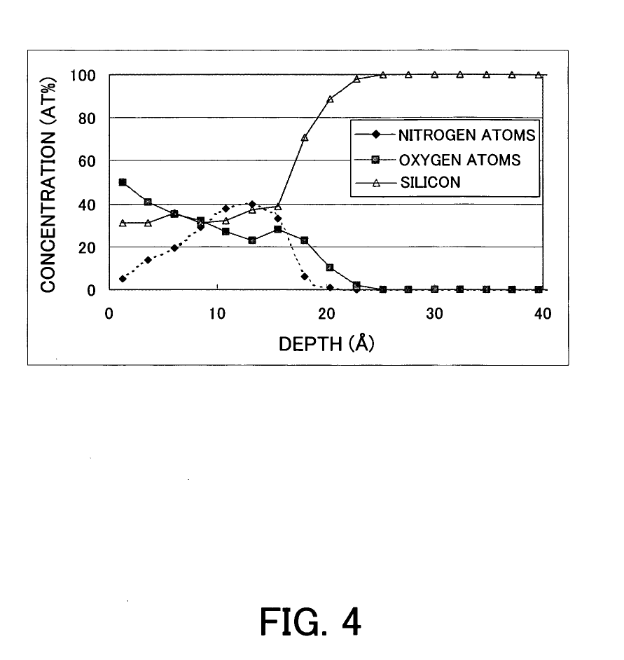

As a result of that an ellipsometer measures a thickness of the silicon oxynitride film, the thickness was found to be 2.3 nm. A Rutherford back scattering spectroscopy (“RBS”) measured the nitrogen concentration distribution in a depth direction in the film showed a distribution shown in FIG. 4, and the surface density of nitrogen introduced in the film was estimated to be about 1.3×10¹⁵ cm^{-2.}

A MOS structure capacitor was produced from the silicon oxynitride film produced by the above processing method, and the electric characteristics of its insulated film were evaluated. As a result, the EOT measurement result in the C-V characteristic was evaluated to be 2.0 nm, and it was confirmed that the nitrogen introduction into the oxide film improved the dielectric constant and realized a low profile effect.

### Second Embodiment

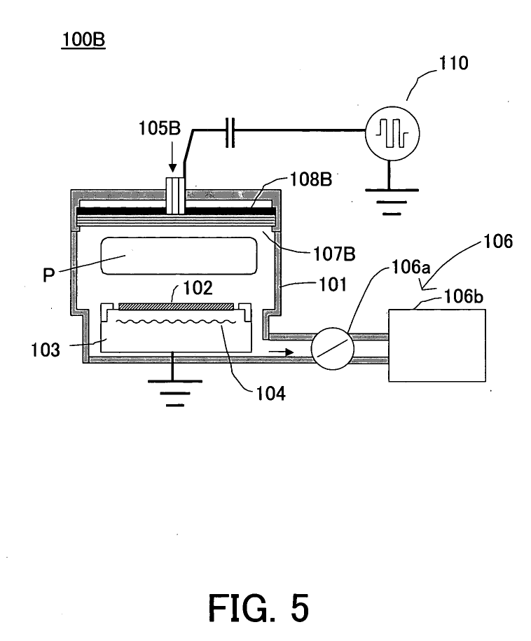

This embodiment used a microwave plasma processing apparatus 100B shown in FIG. 5 as one example of the processing apparatus 100 to form a gate oxide film for a semiconductor device. The processing apparatus 100B uses a high-frequency power source 110 that can excite plasma in a RF manner and project pulsed power, and performed the nitriding and oxidization treatments. The instant embodiment conducted, as shown in FIG. 8, plasma treatments in the different process chambers 301 and 302 for the nitriding and oxidization treatments. Those elements in FIG. 5 which are the same as those in FIG. 1 are designated by the same reference numeral, and which are variations or specific examples of those in FIG. 1 are designated by the same reference numeral with a capital.

The substrate 102 used an 8-inch P-type single crystal silicon substrate with a surface azimuth of <1 0 0> and resistivity of 10 Ωcm. First, the substrate 102 was fed to the plasma process chamber 101 and placed on the susceptor 103. The heater 104 heated the substrate 102 up to 400° C. and maintained the temperature.

Then, the gas introducing part 105B introduced N₂ gas into the process chamber 101 at a flow rate of 200 sccm, to adjust an opening of the pressure control valve 106a in the pressure control mechanism 106, and to hold the pressure in the process chamber 101 to be 63.3 Pa. Then, the high-frequency supply unit 108B supplied 800 W of RF power of 13.56 GHz to the process chamber 101 through the high-frequency transmission means 107B, and generated plasma P in the process chamber 101. The substrate 102 was exposed to the generated nitrogen plasma for 120 seconds to form a silicon nitride film. As a result of that an ellipsometer measured a thickness of the silicon nitride film, the thickness was found to be 2.2 nm.

After the vacuum pump sufficiently draws a vacuum in the process chamber 101 down to 10⁻³ Pa, the gas introducing part 105B introduced O₂ gas at a flow rate of 200 sccm, to adjust an opening of the pressure control valve 106a and to hold the pressure in the process chamber 101 to be 266 Pa. Then, the microwave supply unit 108B supplied 800 W of RF power at 13.56 GHz to the process chamber 101 through the high-frequency transmission window 107B, and generated plasma P in the process chamber 101. The applied voltage for the RF power was incident as pulsed waves with a duty ratio of 30% for reduced electron temperature in the plasma. As a result of probe measurements, it was found that the sheath potential generated in the substrate changed, the incident oxygen-ion energy was reduced to about 4 eV for pulsed RF although RF continuous discharge was about 6 eV. The substrate 102 was exposed to the generated oxygen plasma for 30 seconds to modify it into a silicon oxynitride film.

As a result of that an ellipsometer measured a thickness of the silicon oxynitride film, the thickness was found to be 2.6 nm. The charge damage was evaluated with SCA to investigate damages in the insulated film as a result of oxygen ion implantations. As a consequence, the fixed charge density was 6.3×10¹¹ qcm⁻² for high incident ion energy conditions, whereas the fixed charge density was 3.7×10¹¹ qcm⁻² for low incident ion energy conditions.

### Third Embodiment

The third embodiment used different plasma excitation means for the nitriding and oxidization treatments. First, this embodiment formed a silicon nitride film using the processing apparatus 100A for the nitriding treatment.

The substrate 102 used an 8-inch P-type single crystal silicon substrate with a surface azimuth of <1 0 0> and resistivity of 10 Ωcm. First, the substrate 102 was fed to the plasma process chamber 101 and placed on the susceptor 103. The heater 104 heated the substrate 102 up to 400° C. and maintained the temperature.

Then, mixed gas of N₂ and He was introduced at flow rates of 50 sccm and 450 sccm, respectively, into the plasma process chamber 101 to adjust an opening of the pressure control valve 106a, and to hold the pressure in the process chamber 101 to be 26.6 Pa. Then, the microwave supply unit 108A supplied 1 kW microwave power at 2.45 GHz to the process chamber 101 through the dielectric window 107, and generated plasma P in the process chamber 101. The substrate 102 was exposed to the generated nitrogen plasma for 20 seconds to form a silicon nitride film. As a result of that an ellipsometer measured a thickness of the silicon nitride film, the thickness was found to be 1.7 nm.

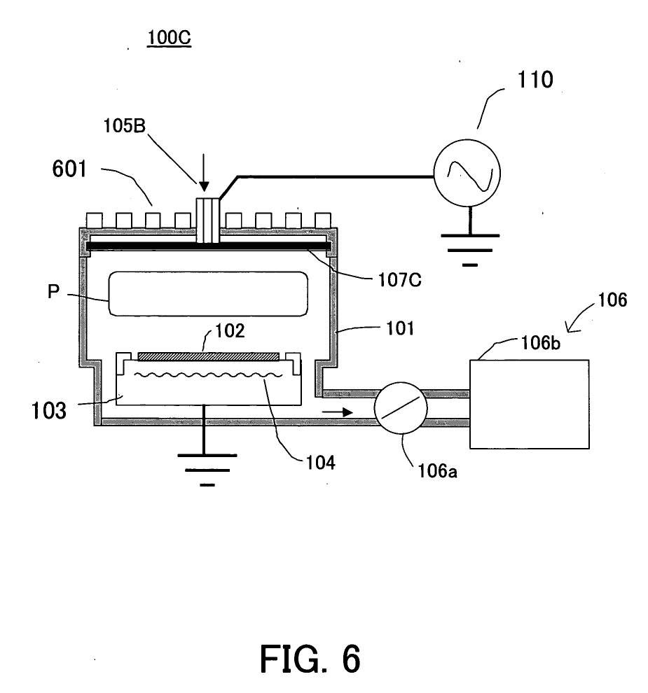

The plasma oxidation treatment used an RF magnetron excitation plasma processing apparatus shown in FIG. 6. The silicon nitride film was fed to the oxidation process chamber 302, and placed on the susceptor 103. The heater heated the nitrided substrate 102 up to 300° C., and maintained the temperature. The gas introducing part 105B introduced mixed gas of O₂ and Ar at flow rates of 20 sccm and 180 sccm, respectively, to adjust an opening of the pressure control valve 106a and to hold the pressure in the process chamber 101 to be 400 Pa. Then, 800 W of RF power at 13.56 GHz was applied to an electrode and projected through the high-frequency transmission window 107C, and generated plasma P in the process chamber 101. The substrate 102 was exposed to the generated oxygen plasma for 45 seconds to modify it into a silicon oxynitride film. As a result of that an ellipsometer measured a thickness of the silicon oxynitride film, the thickness was found to be 2.3 nm.

A MOS structure capacitor was produced from the silicon oxynitride film produced by the above processing method, and the electric characteristics of its insulated film were evaluated. Then, an excellent result was obtained, such as the fixed charge density of about 2.2×10¹¹ cm⁻² and the interface level density of about 6.5×10¹¹ eV⁻¹.

### Fourth Embodiment

This embodiment used the plasma processing apparatus 100A to nitride and oxide a silicon substrate to form a silicon oxynitride film, and then formed a gate oxide film for a semiconductor device by forming a hafnium oxide.

The substrate 102 used an 8-inch P-type single crystal silicon substrate with a surface azimuth of <1 0 0> and resistivity of 10 Ωcm. First, the substrate 102 was fed to the plasma process chamber 101 and placed on the susceptor 103. The heater 104 heated the substrate 102 up to 300° C., and maintained the temperature.

Then, N₂ gas was introduced at a flow rate of 550 sccm into the plasma process chamber 101, to adjust an opening of the pressure control valve 106a and maintain the pressure in the process chamber 101 to be 133 Pa. Then, the microwave supply unit 108A supplied 1 kW microwave power at 2.45 GHz to the process chamber 101 through the dielectric window 107, and generated plasma P. The substrate 102 was exposed to the generated nitrogen plasma for 60 seconds to form a silicon nitride film. As a result of that an ellipsometer measured a thickness of the silicon nitride film, the thickness was found to be 1.7 nm.

After the vacuum pump sufficiently draws a vacuum in the process chamber 101 down to 10⁻³ Pa, mixed gas of O₂ and He was introduced at flow rates of 20 sccm and 180 sccm, respectively, to adjust an opening of the pressure control valve 106a and maintain the pressure in the process chamber 101 to be 266 Pa. Then, the microwave supply unit 108A supplied 0.1 kW microwave power at 2.45 GHz to the process chamber 101 through the dielectric window 107, and generated plasma P. The substrate 102 was exposed to the generated oxygen plasma for 20 seconds to modify it into a silicon oxynitride film.

A hafnium oxide film was formed through an RTO oxidation after a sputtering method deposited hafnium with a thickness of 2 nm on the silicon oxynitride film on the substrate 102.

A MOS structure capacitor was produced from the silicon oxynitride film produced by the above processing method, and the electric characteristics of its insulated film were evaluated. An excellent result was obtained, such as EOT of 2.5 nm, the fixed charge density of 2.8×10¹¹ cm⁻², and the interface level density of 6.9×10¹⁰ eV⁻¹ cm⁻².

As discussed, the plasma oxidation subsequent to the plasma nitriding on the semiconductor substrate would be able to not only form, at a low temperature, the high-quality silicon oxynitride film with less defects, such as interface level and fixed charge, but also produce high performance MOS devices using the same.

Further, the present invention is not limited to these preferred embodiments, but various modifications and variations may be made without departing from the spirit and scope of the present invention.

The present invention can provide a processing apparatus and method that forms, without using a heated high-temperature atmosphere, a reliable insulated film, more specifically, a high-quality insulated film that has a high dielectric constant and a low fixed charges and interface level density. In addition, nitrogen atoms introduced into the insulated film can prevent diffusions of impurities, such as boron, towards the substrate, and the insulated film can be used singularly or as a primary coat for a high dielectric-constant material.

1. A processing method for forming an insulated film on a surface of a substrate to be processed, through an oxynitriding treatment, said processing method comprising the steps of:
nitriding a surface of the substrate by irradiating plasma containing nitrogen atoms onto the substrate; and
oxidizing the surface of the substrate, which has been nitrided, by irradiating plasma containing oxygen atoms.

2. A processing method according to claim 1, wherein said nitriding and oxidizing steps place the substrate on a susceptor, a temperature of the susceptor being maintained at 600° C. or lower.

3. A processing method according to claim 1, wherein said substrate include silicon, and said nitriding and oxidizing steps control a process time so that the insulated film has an effective oxide thickness of 3.0 nm or smaller.

4. A processing method according to claim 1, wherein said nitriding step uses, as process gas, gas that includes at least one of N₂, NH₃ and N₂H₄ or the one which is diluted with at least one of He, Ne, Ar, Kr and Xe, mixed gas of H₂+N₂ or the one which is diluted with at least one of He, Ne, Ar, Kr and Xe.

5. A processing method according to claim 1, wherein said oxidizing step gas uses, as process gas, gas that includes at least one of O₂, O₃, H₂O, and H₂O₂ or the one which is diluted with at least one of He, Ne, Ar, Kr, Xe and N₂.

6. A processing method according to claim 1, wherein said oxidizing step sets ion energy to be 5 eV or smaller incident to the substrate from the plasma.

7. A processing method according to claim 1, wherein said substrate includes silicon, and said oxidizing step controls an oxygen atom concentration so that a nitrogen atom concentration is 5% or smaller at a position near an interface between the silicon and a silicon oxynitride film in the insulated film.

8. A processing method according to claim 1, wherein said nitriding step controls a process time so that the insulated film contains the nitrogen atoms between 3×10 ¹⁴ cm⁻² and 1.5×10¹⁵ cm⁻² that is converted into a surface density.
